(19) United States
(12) Patent Application Publication
(10) Pub. No.: US 2006/0003570 A1
(43) Pub. Date: Jan. 5, 2006

(54) Method and apparatus for electroless capping with vapor drying

(76) Inventors: Arulkumar Shanmugasundram, Sunnyvale, CA (US); Robert D. Tolles, San Jose, CA (US); Russel Ellwanger, San Juan Bautista, CA (US)

Correspondence Address: PATTERSON & SHERIDAN, LLP, 3040 POST OAK BOULEVARD, SUITE 1500, HOUSTON, TX, 77056, US

(21) Appl. No.: 11/004,014

(22) Filed: Dec. 2, 2004

Related U.S. Application Data
(60) Provisional application No. 60/526,675, filed on Dec. 2, 2003.

(51) Int. Cl. H01L 21/4763; H01L 21/44

(52) U.S. Cl. 438/618; 438/638; 438/678

(57) ABSTRACT

Embodiments of the invention relate to a method and apparatus for forming an electroless capping layer over the copper features of a substrate including one or more vapor drying steps. An embodiment of the method includes vapor drying the substrate; optionally applying a dielectric clean solution to the substrate; optionally applying a metal clean solution to the substrate; forming a capping layer by electroless deposition selectively over exposed metal portions of the substrate; and optionally applying a post-deposition clean solution to the substrate structure. In one example, a vapor drying step may be performed prior to forming the capping layer. In another example, the vapor drying step may be performed after forming the capping layer. In another example, a vapor drying step may be performed prior to applying the dielectric clean solution or applying the metal clean solution. In still another example, a vapor drying step may be performed after applying a post-deposition clean solution.

### CROSS-REFERENCE TO RELATED APPLICATIONS

This application claims benefit of U.S. Provisional Patent Application Ser. No. 60/526,675, filed Dec. 2, 2003, which is herein incorporated by reference.

### BACKGROUND OF THE INVENTION

1. Field of the Invention

Embodiments of the invention generally relate to a method and apparatus for forming an electroless capping layer over copper features including one or more vapor drying steps.

2. Description of the Related Art

Reliably producing sub-micron and smaller features is one of the key technologies for the next generation of very large scale integration (VLSI) and ultra large scale integration (ULSI) of semiconductor devices. However, as the fringes of circuit technology are pressed, the shrinking dimensions of interconnects in VLSI and ULSI technology have placed additional demands on the processing capabilities. The multilevel interconnects that lie at the heart of this technology require precise processing of high aspect ratio features, such as vias and other interconnects. Reliable formation of these interconnects is very important to VLSI and ULSI success and to the continued effort to increase circuit density and quality of individual substrates.

As circuit densities increase, the widths of vias, contacts and other features, as well as the dielectric materials between them, decrease to sub-micron dimensions, whereas the thickness of the dielectric layers remains substantially constant, with the result that the aspect ratios for the features, i.e., their height divided by width, increases. Many traditional deposition processes have difficulty filling sub-micron structures where the aspect ratio exceeds 2:1, and particularly where the aspect ratio exceeds 4:1. Therefore, there is a great amount of ongoing effort being directed at the formation of substantially void-free, sub-micron features having high aspect ratios.

In order to further reduce the size of devices on integrated circuits, it has become necessary to use conductive materials having low resistivity and insulators having low k (dielectric constant<4.0) to reduce the capacitive coupling between adjacent metal lines. Currently, copper and its alloys have become the metals of choice for sub-micron interconnect technology because copper has a lower resistivity than aluminum, (1.7 μΩ-cm compared to 3.1 μΩ-cm for aluminum), and a higher current carrying capacity and significantly higher electromigration resistance. These characteristics are important for supporting the higher current densities experienced at high levels of integration and increased device speed. Further, copper has a good thermal conductivity and is available in a highly pure state.

One problem with the use of copper and its alloys is that copper readily oxidizes when exposed to air and is vulnerable to chemical corrosion and deterioration due to subsequent processing steps. One method of protecting copper interconnects from subsequent processing steps is to form a passivation layer over a planarized copper feature. Examples of passivation materials include silicon nitride (i.e. Si₃N₄) and low k materials (such as BLOK™ materials from Applied Materials, Inc, of Santa Clara, Calif.). FIG. 1 is a schematic cross-sectional view of one example of substrate structure 10 including copper features 12 formed in apertures 15 formed in dielectric layers 14, such as a low k dielectric layer, and passivation layers 16 formed over the copper features 12 and over the dielectric layers 14 to protect the copper from subsequent processing steps. Typically, a barrier layer 13 is formed over the apertures 15 before the deposition of copper in order to prevent diffusion of the copper into the dielectric layer 14.

One problem with the use of dielectric passivation layers is that over time voids may form and/or shorts may occur from the electromigration and stress migration of copper between interconnect features due to the sensitive boundary between copper features and the passivation layer. Another problem with the use of dielectric passivation layers is the high overall dielectric constant of the film stack of a low k dielectric material and the dielectric passivation layer. This high overall dielectric constant reduces the benefits of using low k dielectric materials.

One approach to protecting copper interconnects is to form a capping layer over copper interconnects. One problem with previous capping layer methods is inadequate pre-treatment of the wafer prior to electroless deposition of the capping layer and inadequate post-treatment of the capping layer, which may cause contamination problems and/or selectivity problems. One example of contamination includes watermarks remaining on hydrophobic films that contain copper, cobalt, and other metals.

Therefore, there is a need for an improved method of forming a capping layer over copper interconnect features.

### SUMMARY OF THE INVENTION

Embodiments of the invention relate to a method and apparatus for forming an electroless capping layer over features on a surface of substrate and for performing one or more vapor drying steps before or after forming the electroless capping layer. One embodiment of the method includes vapor drying a substrate; and forming a capping layer by an electroless deposition process over an exposed metal portion formed on a surface of the substrate.

Another embodiment of the method includes cleaning a surface of a substrate by cleaning a surface of a substrate by performing a dielectric clean process; cleaning a surface of a substrate by performing a metal clean process; forming a capping layer by electroless deposition selectively over exposed metal portions of the substrate structure; and cleaning a surface of a substrate by performing a post-deposition process. One or more vapor drying steps may be performed during the method. In one example, a vapor dry step may be performed prior to cleaning the substrate surface using a dielectric clean process. In another example, a vapor dry step may be performed after cleaning the substrate surface using a dielectric clean process. In still another example, a vapor dry step may be performed after cleaning the substrate using a post-deposition clean process.

In one embodiment, a fluid processing platform is adapted to process a substrate having a substrate structure formed thereon, comprising a first processing chamber, wherein the first processing chamber is an electroless deposition chamber; and a second processing chamber, wherein the second processing chamber is a vapor drying chamber.

In another embodiment a fluid processing platform is adapted to process a substrate having a substrate structure formed thereon, comprising a first processing chamber, wherein the first processing chamber is adapted to deposit an activation metal seed layer by use of an electroless process; a second processing chamber, wherein the second processing chamber is adapted to deposit a capping layer by use of an electroless process; and a vapor drying chamber that is adapted to process a substrate in a substantially vertical orientation.

In yet another embodiment a fluid processing platform adapted to process a substrate having a substrate structure formed thereon, comprising: an electroless processing chamber that is adapted to process a substrate in a substantially horizontal orientation; a vapor drying chamber that is adapted to process a substrate in a substantially vertical orientation; and a wet processing chamber that is adapted to perform a process selected from a group consisting of a dielectric clean chamber, a copper clean chamber, an electroless activation layer deposition chamber, a post-activation clean chamber, or a combined chamber adapted to perform a combination thereof.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of one example of a substrate structure including passivation layers formed over copper features to protect the copper from subsequent processing steps.

FIG. 2 is a schematic cross-section view of one example of a substrate structure prior to formation of an electroless capping layer over a copper feature.

FIG. 3 is a schematic cross-section view of one example of the substrate structure of FIG. 2 after formation of an electroless capping layer over the copper feature.

FIG. 4 is a flow chart of one embodiment of a method of forming an electroless capping layer over conductive features of a substrate structure with one or more vapor drying steps.

FIG. 5 is a flow chart of another embodiment of a method of forming an electroless capping layer over conductive features of a substrate structure with one or more vapor drying steps.

FIG. 6 is a flow chart of yet another embodiment of a method of forming an electroless capping layer over conductive features of a substrate structure with one or more vapor drying steps.

FIG. 7 is a schematic side view of one embodiment of a vapor drying apparatus.

FIG. 8A is a schematic top view of one embodiment of an integrated processing system.

FIG. 8B is a schematic top view of another embodiment of an integrated processing system.

FIG. 9 is a schematic cross-sectional view of one example of a substrate structure including copper features capped with a capping layer.

FIG. 10 is a schematic cross-sectional view of one embodiment of a cleaning module that may be adapted to perform various aspects of the invention described herein.

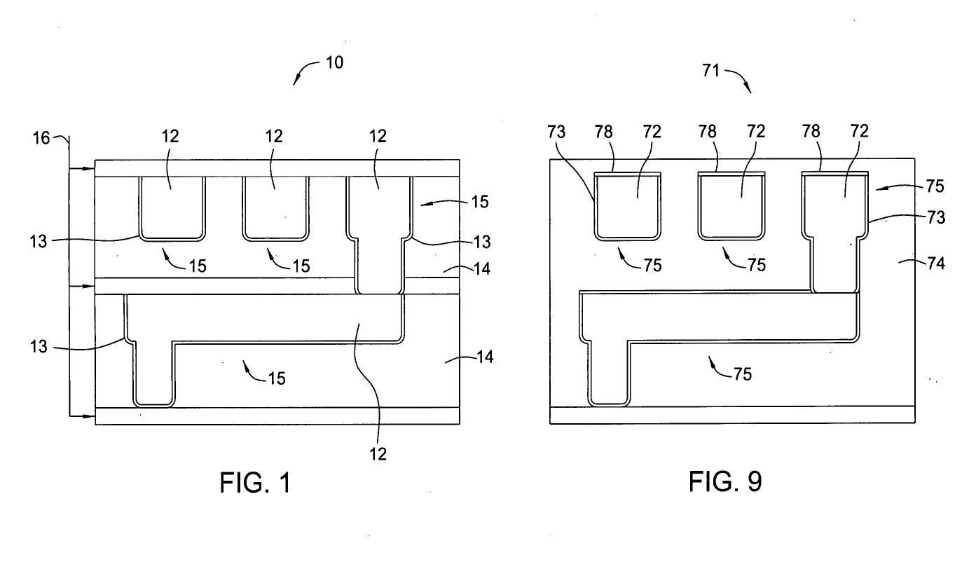

### DETAILED DESCRIPTION OF THE PREFERRED EMBODIMENT

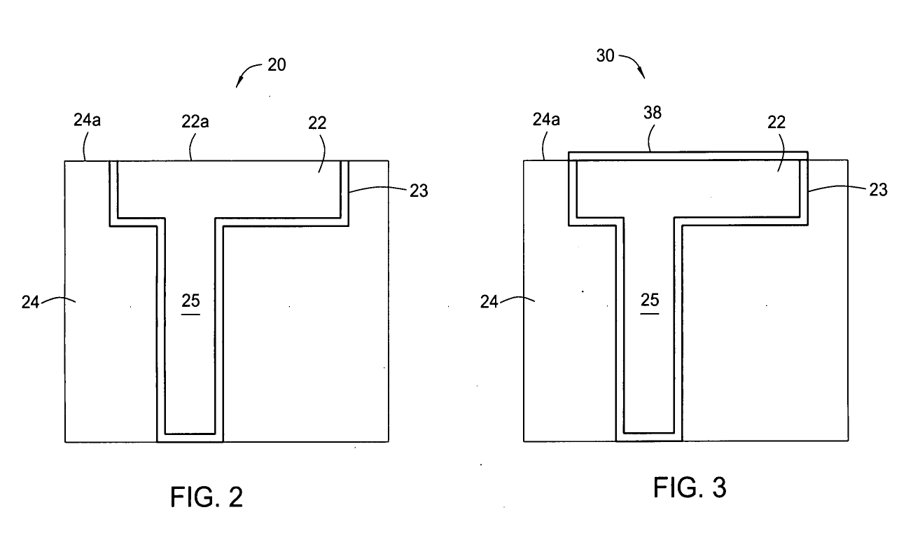

Embodiments of the invention relate to a method and apparatus for forming an electroless capping layer over copper features including one or more vapor drying steps. FIG. 2 is a schematic cross-section view of one example of a substrate structure 20 prior to formation of an electroless capping layer over a copper feature. The substrate structure 20 includes a low-k dielectric layer 24 formed over a substrate, such as a semiconductor substrate or glass substrate, or formed over a substrate as well as other materials formed over the substrate. Examples of low-k materials include Black Diamond™ film, available from Applied Materials, Inc. of Santa Clara, Calif.; CORAL™ film, available from Novellus Systems Inc. of San Jose, Calif., AURORA™ film available from ASM International of Bilthoven, Netherlands; organosilanes or organosiloxanes; spin on dielectrics; carbon doped oxides; silicates; and any other suitable material. Examples of the deposition of organosilanes and organosiloxanes is described in U.S. Pat. No. 6,348,725, issued Feb. 19, 2002, which is incorporated by reference herein to the extent not inconsistent with the present disclosure.

The low-k dielectric layer 24 is patterned and etched to form an aperture 25, such as a via, trench, contact hole, or line. A barrier layer 23, such as a tantalum-containing barrier layer or other suitable barrier layer, is formed over the aperture 25. Then, a copper layer 22 is formed over the barrier layer filling the aperture 25. A seed layer (not shown), such as a copper seed layer, a copper alloy seed layer, or other suitable seed layer, may be formed between the barrier layer 23 and the copper layer 22 to help deposition of the copper layer 22. The copper layer 22, the seed layer, and the barrier layer 23 are typically removed from the upper surface of the low-k dielectric layer 24 through planarization techniques, such as chemical mechanical polishing (CMP). Thus, the upper surface of the substrate structure 20 includes an exposed portion 24a of the low-k dielectric layer 24 and an exposed portion 22a of the copper layer 22.

FIG. 3 is a schematic cross-section view of one example of the substrate structure 30 after formation of an electroless capping layer 38 over the copper feature. The electroless capping layer 38 is formed over conductive surfaces, such as the exposed portion 22a of the copper layer 22, and does not form over the exposed portion 24a of the low-k dielectric layer 24. Thus, patterning and etching steps are not required to remove the electroless capping layer from the low-k dielectric layer 24. In one aspect, the electroless capping layer 38 helps protect the copper layer 22 from oxidizing during subsequent processing steps. In another aspect, the electroless capping layer 38 helps prevent diffusion of copper into surrounding layers and layers that are later formed over the exposed portion 24a and exposed portion 22a. In still another aspect, the electroless capping layer 38 helps prevent the formation of vacancies in the surface of the copper layer and surface migration of copper. In yet another aspect, the electroless capping layer 38 makes the use of a passivation layer optional. The elimination of a passivation layer helps lower the capacitance resistance. For example, in some instances a capacitance resistance is lowered by 35%.

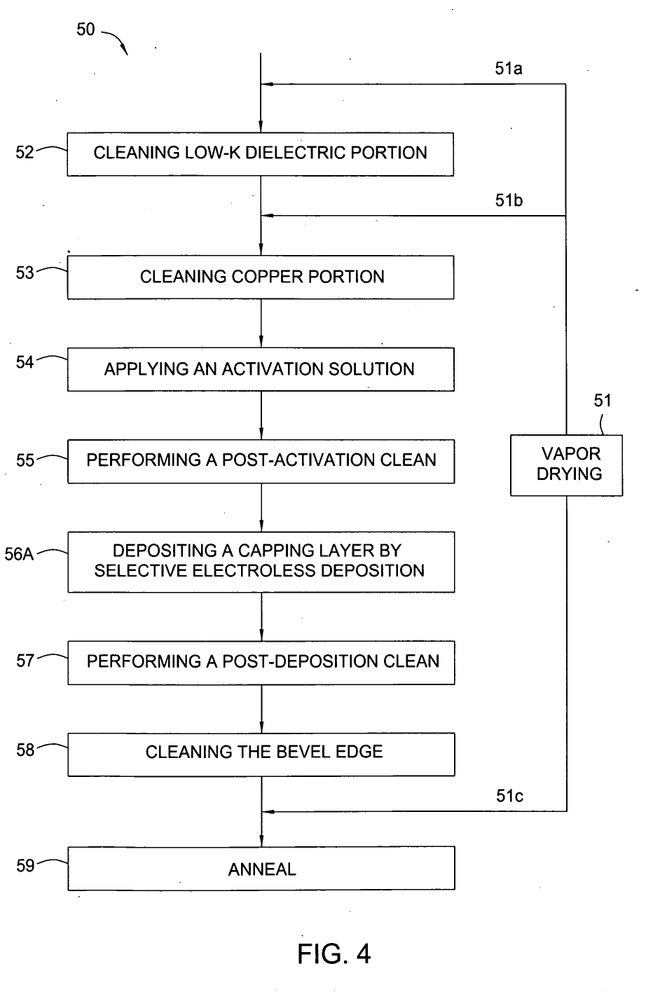

FIGS. 4-6 illustrate various embodiments of methods (e.g., methods 50, 60, and 70) of forming an electroless capping layer over conductive features of a substrate structure which contain one or more vapor drying steps. For clarity of description, the methods 50, 60 and 70 will be described in reference to the substrate structure 20 of FIG. 2. In other embodiments, the methods 50, 60 and 70 may include processing a substrate structure formed using other dielectric materials and/or other conductive materials (e.g., tungsten, aluminum, and other metals) with out varying from the basic scope of the invention.

FIG. 4 is a flow chart of one embodiment of a method 50 of forming an electroless capping layer over conductive features of a substrate structure with one or more vapor drying steps. In other embodiments, one or more steps of method 50 may be optionally performed. In other embodiments, the sequence of steps of method 50 may be rearranged, altered or two or more steps may be combined into a single step with out varying from the basic scope of the invention.

In step 52, an exposed portion 24a of the low-k dielectric layer 24 may be cleaned by applying a dielectric clean solution to the substrate structure. The dielectric clean solution may include one or more acids (such as citric acid, HF, and/or HCl) and may include one or more corrosion inhibitors capable of inhibiting corrosion of the conductive metal. The corrosion inhibitors may include any of various chemical compounds, for example organic compounds containing an azole group, such as benzotriazole, mercapto-benzotriazole, or 5-methyl-1-benzotriazole. A further description of dielectric solution chemistries (e.g., pre-clean process chemistries and complexing agent solutions) and process of cleaning the substrate structure as described herein may be found in commonly assigned U.S. patent application Ser. No. 10/970,839, entitled, “Electroless Cobalt Alloy Deposition Process,” filed on Oct. 21, 2004, and commonly assigned U.S. patent application Ser. No. 10/967,644, entitled, “Selective Self-Initiating Electroless Capping of Copper With Cobalt-Containing Alloys,” filed Oct. 15, 2004, both of which are incorporated by reference herein to the extent not inconsistent with the claimed aspects and description herein. Cleaning of the low-k dielectric may further include brushing the substrate surface and/or applying ultrasonic or megasonic energy to the substrate structure by use of sonic transducers.

An exemplary apparatus and method of applying ultrasonic or megasonic energy to clean a substrate structure useful for completing steps 52, 53, 55, 57 and/or 58 are disclosed in U.S. patent application Ser. No. 10/425,260, entitled “Semiconductor Substrate Cleaning System,” filed on Apr. 29, 2003, U.S. Patent Application Publication 2002/0074023, entitled “Apparatus for Cleaning and Drying Substrates,” and U.S. patent application Ser. No. 09/891,849, entitled “Method and Apparatus For Wafer Cleaning”, filed Jun. 25, 2001, which are incorporated by reference herein to the extent not inconsistent with the claimed aspects and description herein.

An exemplary apparatus and method of brush cleaning a substrate structure useful for completing steps 52, 53, 55, 57 and/or 58 are disclosed in U.S. Pat. No. 6,558,471, entitled “Scrubber Operation,” and U.S. Pat. No. 6,299,698, entitled “Wafer Edge Scrubber and Method”, which are incorporated by reference herein to the extent not inconsistent with the claimed aspects and description herein.

Not wishing to be limited by theory unless explicitly set forth in the claims, it is believed that the dielectric clean solution removes metallic residues from the exposed portion 24a of the low-k dielectric layer 24. It is also believed that the corrosion inhibitor protects the exposed portion 22a of the copper layer 22 during the dielectric clean. If metallic residues are not removed, electroless deposition of the capping material may occur over these metallic residues and possibly cause an electrical short between the devices formed on or above the substrate structure 20. In one embodiment, a thickness of less than about 50 Å, preferably less than about 30 Å, of the copper layer 22 and a thickness of less about 50 Å, preferably less than about 30 Å, of the dielectric layer 24 is etched by the dielectric clean solution.

In step 53, an exposed portion 22a of the copper layer 22 may be cleaned by applying a copper clean solution to the substrate structure. One example of a suitable copper clean solution is a Electra Clean™ solution commercially available from Applied Materials, Inc., of Santa Clara, Calif. or a CX-100 solution available from Wako Chemicals USA, Inc. of Richmond Va. Another example of a suitable copper clean solution includes sulfuric acid and HCl. Still another example of a suitable copper clean solution includes citric acid and peroxide. Cleaning of the copper layer may further include brushing the substrate structure and/or applying ultrasonic or megasonic energy to the substrate structure by use of sonic transducers.

It is believed that the copper clean solution removes copper oxides, removes the dielectric clean solution of step 52 and other possible contaminants from the exposed portion 22a of the copper layer 22. For example, the copper clean solution may remove the corrosion inhibitor of the dielectric clean solution remaining on the exposed portion 22a of the copper layer 22. Corrosion inhibitor remaining on the exposed portion 22a of the copper layer may inhibit formation and/or adhesion of the capping material thereover in a subsequent processing step. In one embodiment, a thickness of less than about 50 Å, preferably less than about 30 Å, of the copper layer 22 and a thickness of less about 50 Å, preferably less than about 30 Å, of the dielectric layer 24 is etched by the copper clean solution. In another embodiment, step 52 and step 53 are preferably separate steps to ensure adequate cleaning of the exposed portion 24a of the low-k dielectric layer 24 and adequate cleaning of the exposed portion 22a of the copper layer 22.

In step 54, an activation solution may be applied to the substrate structure to deposit an activation metal seed layer. Examples of suitable materials for the activation metal seed layer include palladium, silver, rhenium, ruthenium and combinations thereof. Preferably, the activation metal seed layer includes palladium. One example of an activation solution for depositing a palladium activation metal seed layer is a solution containing one or more palladium salts. Examples of palladium salts include chlorides, bromides, fluorides, fluoborates, iodides, nitrates, sulfates, carbonyls, salts of metal acids, and combinations thereof. Preferably, the palladium salts are chlorides, such as palladium chloride (PdCl₂), chloroplatinic acid (H₂PtCl₆), and combinations thereof. In one embodiment, the queue time between the end of step 53 and the beginning of step 54 may be less than about 15 seconds, preferably less than about 5 seconds, to substantially prevent oxidation of the exposed portion 22a of the copper layer. One exemplary process and method of depositing an activation metal seed layer, completing a post-activation clean step (step 55 discussed below), depositing a capping layer (step 56A discussed below) and post-deposition clean step (step 57 discussed below) is disclosed in U.S. patent application Ser. No. 10/970,354 [APPM 9237.02], entitled “Electroless Palladium Nitrate Activation Prior To Cobalt-Alloy Deposition,” filed Oct. 21, 2004, which is incorporated by reference in its entirety to the extent not inconsistent with the present disclosure.

In one theory, it is believed that the activation metal seed deposits over a copper material by a displacement mechanism. As a consequence, the activation metal seed forms primarily on the exposed portion 22a of the copper layer. Oxidation of the exposed portion 22a of the copper layer after cleaning thereof may be detrimental to the deposition of the activation metal seed layer since copper oxides may inhibit the displacement mechanism of the activation metal seed layer. In another theory, it is believed that the activation solution deposits an activation metal seed layer which adheres more to conductive surfaces, such as the exposed portion 22a of the copper layer 22. As a consequence, oxidation of the exposed portion 22a of the copper layer after cleaning thereof may be detrimental to deposition of the activation metal seed layer over the exposed portion 22a of the copper layer 22 since copper oxides have a higher resistivity than copper. In one embodiment, a short queue time is used to help prevent oxidation of the exposed portion 22a of the copper layer 22 after cleaning thereof. In another embodiment, an inert gas environment (such as a N₂ environment) helps to prevent oxidation of the exposed portion 22a of the copper layer 22 after cleaning. In one embodiment, step 53 and/or step 54 are performed in a substantially inert gas environment. In one embodiment, the substrate structure remains in an inert gas environment while the substrate structure is being transferred between the different chambers that are used to perform steps 53 and 54. In one embodiment, the steps 53 and 54 are performed in the same processing chamber having a substantially inert environment during processing.

In step 55, a post-activation clean may be performed by applying a post-activation clean solution to the substrate structure. The post-activation clean solution may include one or more acids (such as citric acid, HF, and/or HCl). In one embodiment, the queue time between the end when the activation solution is applied in step 54 and start of when the post-activation clean solution is applied may be less than about 15 seconds, preferably less than about 5 seconds. Post-activation cleaning of the low-k dielectric may further include brushing the substrate structure and/or applying ultrasonic or megasonic energy to the substrate structure by use of sonic transducers.

It is believed that the post-activation clean removes any excess activation solution so that the activation metal seed layer remains primarily on the exposed portion 22a of the copper layer 22. Remaining activation solution on the exposed portion 24a of the dielectric layer 24 may cause undesirable electroless deposition of the capping material thereover. In one embodiment, the queue time is minimized between the end of step 54 and the time when the post-activation clean solution is applied to the substrate in step 55.

In step 56A, a capping layer may be deposited by selective electroless deposition over the activation metal seed layer and exposed portion 22a of the copper layer 22 by application of an electroless deposition solution to the substrate structure. The capping layer may include CoP, CoWP, CoB, COWB, COWPB, NiB, or NiWB, and preferably includes COWP or COWPB. The electroless deposition solution may include one or more metal salts and one or more reducing agents depending on the capping layer material to be deposited.

In one aspect of the invention, where a cobalt-containing capping layer is to be deposited, the electroless deposition solution may include a cobalt salt. Examples of cobalt salts include chlorides, bromides, fluorides, fluoborates, iodides, nitrates, sulfates, carbonyls, salts of metal acids, and combinations thereof. Preferably, the cobalt salt includes cobalt sulfate, cobalt chloride or combinations thereof. If a tungsten-containing capping material is to be deposited, the electroless deposition solution may include a tungsten salt. Examples of tungsten salts include salts of metal acids, such as ammonium tungstate or tetramethyl ammonium tungstate. Preferably, the tungsten salt includes ammonium tungstate. If a nickel-containing capping layer is to be deposited, the electroless solution may include a nickel salt. Examples of nickel salts include chlorides, bromides, fluorides, fluoborates, iodides, nitrates, sulfates, carbonyls, salts of metal acids, and combinations thereof.

In one aspect of the invention, where the capping layer includes phosphorus, such as CoP, COWP, or COWPB, the electroless deposition solution contains a reducing agent preferably comprising a phosphorus compound, such as phosphoric acid. If the capping layer includes boron, such as CoB, CoWB, COWPB, the reducing agent preferably includes a boron compound, such as boric acid, dimethylamine-borane (DMAB), or combinations thereof. Other reducing agents, such as hydrazine, may substitute or be used in addition to the reducing agents above.

In one embodiment, step 56A may be performed with the electroless deposition solution and/or the substrate structure heated to a temperature between about 40° C. and about 85° C. In one aspect, heating the electroless deposition solution and/or the substrate structure increases the electroless deposition rate. In one embodiment, the deposition rate of the capping layer is about 100 Å/min or more, preferably about 200 Å/min or more. In one embodiment, the capping layer is deposited to a thickness between about 100 Å and about 200 Å, preferably about 150 Å. It is believed that deposition of the capping layer to a thickness of more than 200 Å increases the likelihood of undesirable growth of the capping material over the exposed portion 24a of the dielectric layer 24. An exemplary apparatus for performing the steps 54, 55, 56A and 56B (discussed below) is further described in the U.S. patent application Ser. No. ______ entitled “Apparatus For Electroless Deposition Of Metals On Semiconductor Wafers,” [Applied Materials Docket No. APPM 9032] filed Nov. 22, 2004, and the U.S. patent application Ser. No. 10/965,220 [APPM 8707.02], entitled “Apparatus For Electroless Deposition,” filed Oct. 14, 2004, which are incorporated by reference in their entirety to the extent not inconsistent with the present disclosure.

In step 57, a post-deposition clean step may be performed by applying a post-deposition clean solution to the substrate structure, scrubbing the surface of the substrate with a brush like material and/or applying sonic energy to the substrate structure to remove capping layer material that may be present on the exposed portion 24a of the dielectric layer 24. In one embodiment, the post-deposition clean solution may include one or more acids (e.g., citric acid). One example of a post-deposition clean solution is an ElectraClean™ solution, available from Applied Materials Inc. of Santa Clara, Calif. or a CX-100 solution available from Wako Chemicals USA, Inc. of Richmond, Va. In another embodiment, the capping layer material is exposed to a pH basic solution rinse. The pH basic solution rinse solution may have a pH value from about 7.5 to about 12, preferably from about 8 to about 10, and more preferably from about 8.5 to about 9.5. In one embodiment, the pH basic rinse solution has a similar pH value as the cobalt-containing solution that is employed in step 56A. The pH basic rinse solution contains degassed, deionized water and at least one base, preferably, the base may include TMAH, ammonium hydroxide, tetrahydrofuran, pyridine, other ammonium or amine derivatives, complexes thereof, derivatives thereof and combinations thereof. The substrate is exposed to the pH basic solution rinse for about 1 second to about 60 seconds, preferably for about 10 seconds to about 20 seconds.

In step 58, the bevel edge of the substrate may be cleaned to remove any accumulated material therefrom (often called the edge bead) by providing an etchant solution. One example of an etchant solution includes a solution of sulfuric acid, hydrogen peroxide and deionized water. Another example of an etchant solution further includes HCl and/or nitric acid. One apparatus and method of cleaning the bevel edge is disclosed in U.S. Pat. No. 6,516,815, entitled “Edge Bead Removal/Spin Rinse Dry (EBR/SRD) Module,” which is incorporated by reference to the extent not inconsistent with the present disclosure. Another apparatus and method of cleaning the bevel edge is disclosed in U.S. patent application Ser. No. 09/785,815, entitled “Integrated Semiconductor Substrate Bevel Cleaning Apparatus and Method,” which is incorporated by reference in its entirety to the extent not inconsistent with the present disclosure.

In step 59, the substrate structure may be annealed to help outgas any water moisture from the low-k dielectric layer 24. The substrate structure may be heated by a resistive heater or by heat lamps. In one embodiment, the substrate is annealed at a temperature between about 150° C. and about 250° C. The substrate may be annealed in a vacuum or a gas environment (such as a N₂, N₂H₄, and/or H₂ environment). Preferably, the substrate is annealed in a vacuum environment.

At least one vapor drying step 51 is performed in method 50. In one embodiment, a vapor drying step 51a is performed prior to cleaning the low-k dielectric portion in step 52. In another embodiment, a vapor drying step 51b is performed between cleaning the low-k dielectric portion in step 52 and cleaning the copper portion in step 53. In still another embodiment, a vapor drying step 51c is performed subsequent to cleaning the bevel edge in step 58. In other embodiments two or more of the vapor drying steps 51a-c are used in the method 50.

Vapor drying includes introducing a surface tension-reducing volatile compound, such as a volatile organic compound (VOC), to the substrate structure. For example, a VOC may be introduced with a carrier gas (e.g., nitrogen gas) in the vicinity of the liquid adhering to a substrate structure. The introduction of the VOC results in surface tension gradients which cause the liquid to flow off of the substrate, leaving it dry. In one embodiment, the VOC is isopropyl alcohol (IPA). In other embodiments, the VOC may be other alcohols, ketones, ethers, or other suitable compounds. Examples of exemplary vapor drying processes are further described in the commonly assigned U.S. Pat. No. 6,328,814, filed Mar. 26, 1999 [AMAT No. 2894/CMP/RKK] and U.S. patent application Ser. No. 10/737,732, entitled “Scrubber With Integrated Vertical Marangoni Drying”, filed Dec. 16, 2003, which is incorporated by reference in its entirety to the extent not inconsistent with the present disclosure.

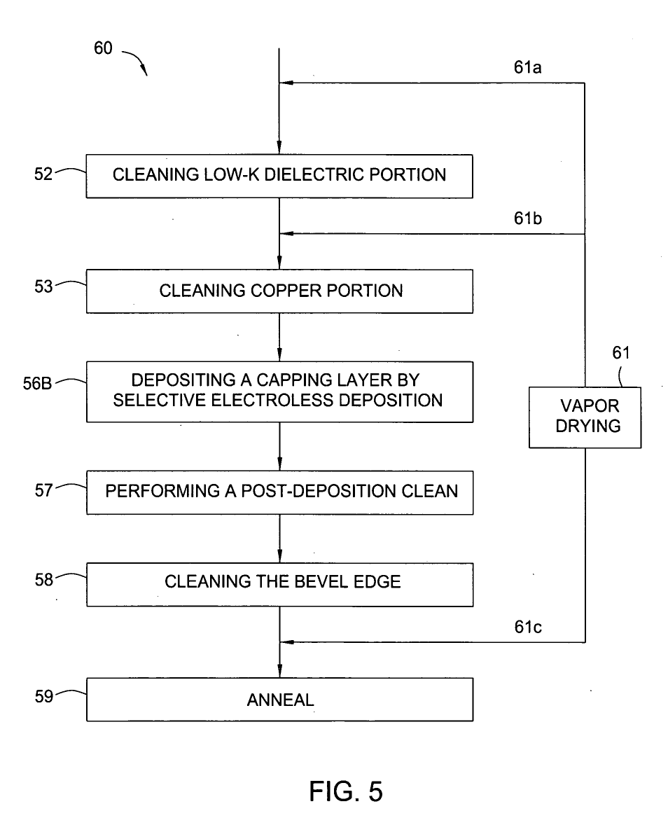

FIG. 5 is a flow chart of another embodiment of a method 60 of forming an electroless capping layer over conductive features of a substrate structure with one or more vapor drying steps. In other embodiments, one or more steps of method 60 may be optionally performed. In other embodiments, the sequence of steps of method 50 may be rearranged, altered or two or more steps may be combined into a single step with out varying from the basic scope of the invention.

The method of FIG. 5 is similar to the method of FIG. 4, and, for clarity of description, like numerals have been used for similar steps where appropriate. In step 52, an exposed portion 24a of the low-k dielectric layer 24 may be cleaned by applying a dielectric clean solution to the substrate structure. In step 53, an exposed portion 22a of the copper layer 22 may be cleaned by applying a copper clean solution to the substrate structure. In step 56B, a capping layer may be deposited by selective electroless deposition over the exposed portion 22a of the copper layer 22 by application of an electroless deposition solution to the substrate structure. In step 57, a post-deposition clean step may be performed by applying a post-deposition clean solution to the substrate structure. In step 58, the bevel edge of the substrate may be cleaned to remove any accumulated material therefrom (often referred to as the edge bead) by providing an etchant solution. In step 59, the substrate structure may be annealed.

In the step 56B of method 60 illustrated in FIG. 5, the capping layer is deposited over exposed portions 22a of the copper layer 22, without previously depositing an activation metal seed layer, by applying a self-activating electroless deposition solution to the substrate structure. The capping layer may include CoB, CoWB, CoWPB, NiB, or NiWB, and preferably includes CoWPB. Not wishing to be bound by theory, it is believed that the inclusion of a boron-containing reducing agent, such as DMAB, in the self-activating electroless solution allows for selective electroless deposition of cobalt-containing capping material over the exposed portion 22a of the copper layer 22 without the need for an activation seed layer. An exemplary method of performing a self-activating electroless deposition process is further disclosed in the commonly assigned U.S. patent application Ser. No. ______ entitled “Self-Activating Electroless Deposition Process For COWP Alloys”, filed Oct. 18, 2004 [APPM 8660.02], which is incorporated by reference in its entirety to the extent not inconsistent with the present disclosure.

Embodiments of the electroless deposition solutions described in reference to method 50 of FIG. 4 and method 60 of FIG. 5 may further contain one or more pH adjusters (such as acids or bases known in the art); one or more surfactants (e.g., RE-610); one or more anti-fungus additives, such as methyl 4-hydroxy benzoic acid; one or more wetting agents; and/or other agents or additives. It is to be understood that in method 50 of FIG. 4 and method 60 of FIG. 5 one or more rinse steps with deionzied water may be performed in conjunction with or between any of the steps.

At least one vapor drying step 61 is performed in method 60. In one embodiment, a vapor drying step 61a is performed prior to cleaning the low-k dielectric portion in step 52. In another embodiment, a vapor drying step 61b is performed between cleaning the low-k dielectric portion in step 52 and cleaning the copper portion in step 53. In still another embodiment, a vapor drying step 61c is performed subsequent to cleaning the bevel edge in step 58. The vapor drying step 61 contains all of the processing aspects described in the vapor drying step 51, and was renumbered to clarify that it is used in another process sequence (e.g., method 60).

Not wishing to be limited by theory unless explicitly set forth in the claims, it is believed that vapor drying the substrate structure in steps 51a-c and 61a-c, of the methods described in reference to FIG. 4 and FIG. 5, assists in the removal of contaminants and other residue from prior processing steps, which may cause, for example, watermarks and other surface defects. The residual compounds are difficult to remove with aqueous solutions from the low-k dielectric portion of the substrate structure since the low-k dielectric portion is a hydrophobic surface. Vapor drying with a volatile organic compound aids in removing the contaminants along with any residual water. Removal of contaminants is particularly important in preventing unwanted electroless deposition of capping material thereover.

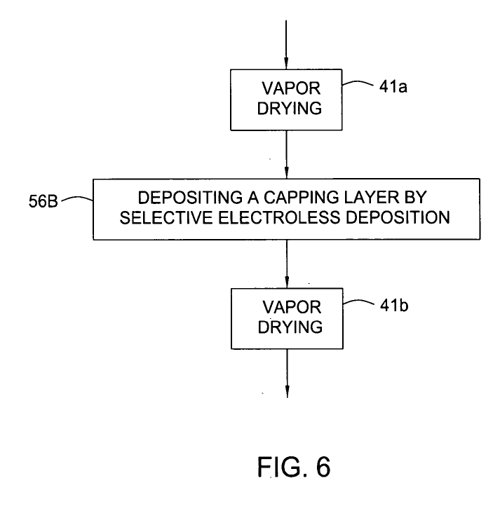

FIG. 6 is a flow chart of one embodiment of a method 70 of forming an electroless capping layer over conductive features of a substrate structure using one or more vapor drying steps. In one embodiment, as illustrated in FIG. 6, a vapor drying process 41 is performed on a substrate before and after forming an electroless capping layer over the conductive features on a substrate surface. The initial vapor drying process, or vapor drying process 41a, is performed prior to completing the electroless capping layer process 56B to prevent watermarks and remove any prior processing residue that may reside on the substrate surface. In one embodiment of method 70, the electroless capping layer process 56B is replaced with the processing steps 54, 55 and 56A, described in method 50. It is generally advantageous to vapor dry a wet or partially wet substrate to prevent water marks or other types of damage that may affect the electroless deposition process and/or the performance of the fabricated device containing the damaged surface. In one embodiment, the substrate is delivered to the initial vapor drying process (step 41a) after it was processed in a CMP tool. The term or phrase “processed in a CMP tool” or “CMP process” is generally meant to describe the process of using a conventional abrasive type CMP material removal process and/or electrochemical material removal process to remove unwanted material(s) from a surface of a substrate. In another aspect of the invention the initial vapor drying process (step 41a) is performed on the substrate after a post-CMP process cleaning step is performed. The post-CMP process cleaning step may be used to remove any residual CMP process material(s) remaining on the surface of the substrate from the prior CMP process(es) performed on the substrate. An example of exemplary chambers and processes that can be used to clean a substrate after performing a CMP process is further described in the U.S. patent application Ser. No. 10/425,260 entitled “Semiconductor Substrate Cleaning System” and filed on Apr. 29, 2003, which is incorporated by reference herein to the extent not inconsistent with the claimed aspects and description herein.

The post vapor drying process, or vapor drying process 41b, is performed after completing the electroless capping layer process (i.e., step 56B or steps 54, 55, 56A) to prevent watermarks and remove any prior processing residue that may reside on the substrate. It is to be understood that in method 70 of FIG. 6 one or more rinse steps with deionized (Dl) water may be performed in conjunction with or between any of the steps. The vapor drying step 41 contains all of the processing aspects described in the vapor drying step 51, and was renumbered to clarify the fact that it is used in another process sequence (e.g., method 70).

In one embodiment of method 70, the vapor drying process 41a is eliminated from the method 70. In another embodiment of method 70, the vapor drying process 41b is eliminated from the method 70.

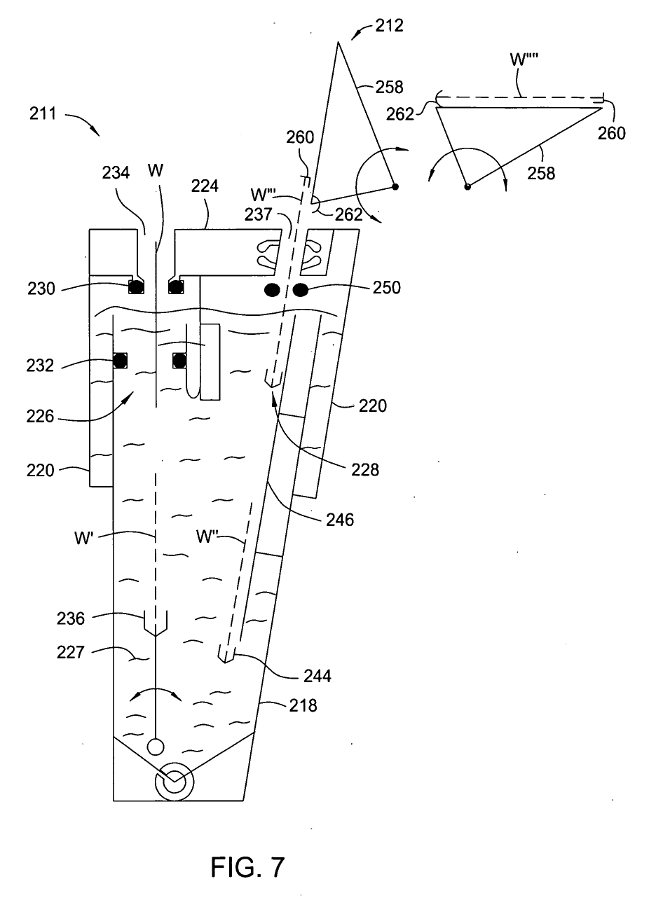

FIG. 7 is a schematic side view of one embodiment of a vapor drying apparatus 211 illustrating a progression of a substrate W through the vapor drying apparatus 211. The progression of the substrate is illustrated by showing the substrate at different positions (W′, W″, W′″, and W″″) as it passes through the vapor drying apparatus 211. The vapor drying apparatus 211 includes a submersion chamber 218 and an upper separation wall 224 that separates a rinsing section 226 from a drying section 228. In operation, a robot (such as a walking beam robot) loads a substrate W into the rinsing section 226 via a load port 234. Nozzles 230, 232 spray DI water onto both sides of the substrate W to remove contaminates therefrom. To aid in removing particles from the rinsing section 226 (i.e., to minimize re-contamination of the substrate), fluid 227 such as DI water or a cleaning solution may be continuously supplied, for example, to the lower portion of the chamber 218 so that fluid continuously overflows to an overflow weir 220 surrounding the chamber 218. Subsequently, the robot releases the substrate W which is received onto a cradle 236, and then retracts from the rinsing section 226 to its home position not shown), above the load port 234. An optical sensor (not shown) detects the presence of the substrate W′ on the cradle 236, and signals an actuator to actuate a linkage system that causes the cradle 236 to rotate from a vertical position to an inclined position (e.g., 90), for subsequent elevation through the drying section 228. Using a pusher 244, the substrate W″ is lifted towards an unload port 237. As the wafer is lifted, the wafer edges lean by the force of gravity on the two parallel inclined guides 246 (only one shown) which are submerged in the fluid. As the substrate W′″ is lifted out of the fluid 227, a pair of spray mechanisms 250 spray an IPA vapor and nitrogen mixture at the meniscus that forms on both sides of the substrate W′″. The specific angle of the flow of the IPA and nitrogen mixture may vary depending upon the type of material on the wafer to be dried. As the substrate W′″ exits the drying section 228 it pushes a catcher 260 causing the catcher 260 to move upward as the pusher 244 moves the substrate W′″ onto the platform 258, after which a finger 262 may lock to secure the substrate W′″ on the platform 258, thereby allowing the pusher 244 to retract. After the substrate W′″ is secured on the platform 258, the platform 258 rotates to its horizontal position where a wafer handler (not shown) may extract the substrate W″″ therefrom. The platform 258 then returns to its vertical position ready to receive the next processed wafer when it is elevated from the drying section 228. A more detailed description of embodiments of an apparatus and method of vapor drying is disclosed in U.S. Patent Application Publication No. 2003/0121170, entitled “Single Wafer Dyer and Drying Methods,” which is incorporated in its entirety to the extent not inconsistent with the present disclosure.

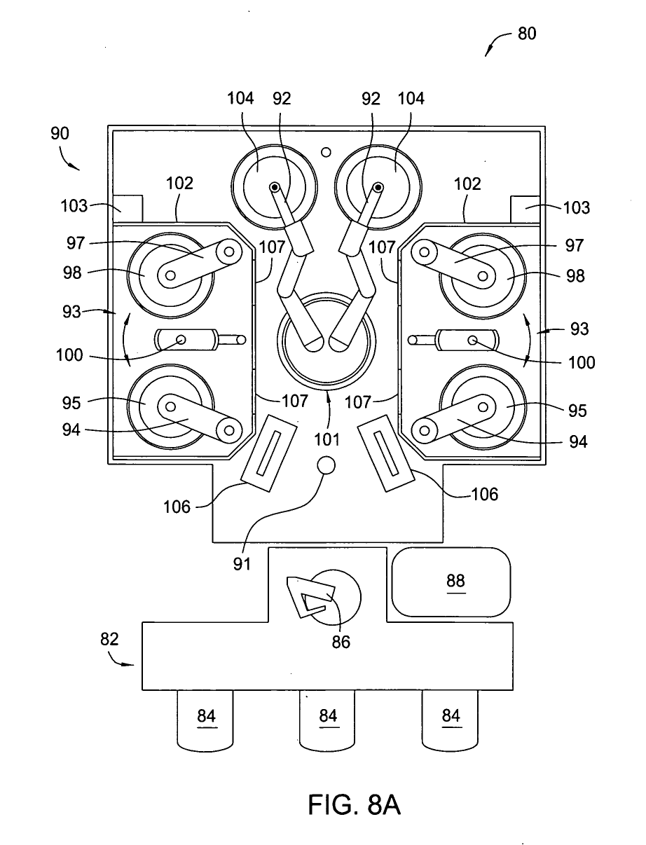

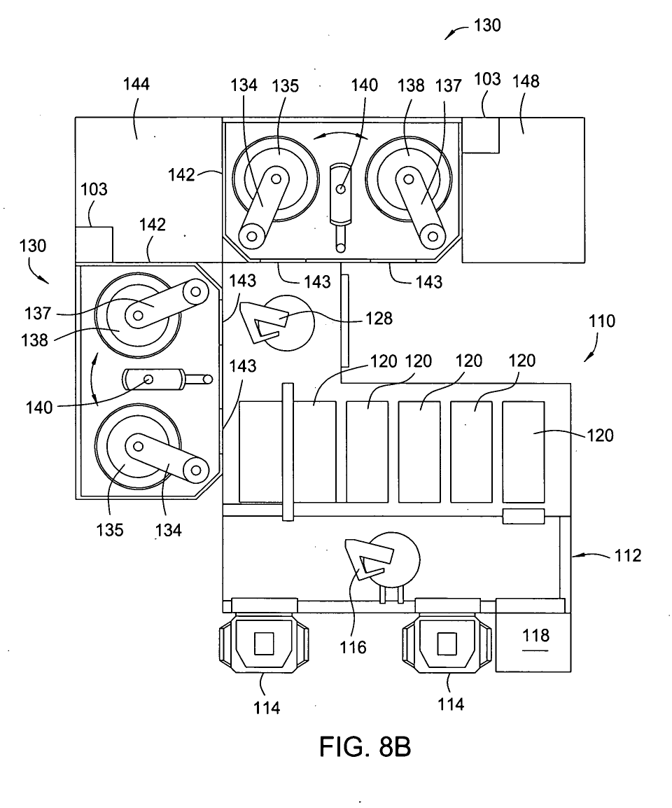

FIG. 8A is a schematic top view of one embodiment of an integrated processing system 80 which may be utilized to perform methods 50-70. Of course, many other processing systems may also be used. The integrated processing system 80 includes a plurality of chambers or cells. In one aspect, it is preferable to perform certain steps in different chambers to reduce the likelihood of cross-contamination from the different chemical solution being used. However, in performing certain steps in different chambers, the issue of queue time between the chambers may impact the particular selection and/or configuration of the various chambers.

Integrated processing system 80 includes a factory interface 82, a wet processing module 90, and a anneal module 88. The factory interface includes a plurality of bays, each accepting a substrate storage cassette 84, and at least one robot 86 to transfer substrates between the substrate storage cassettes 84, the wet processing module 90, and the anneal module 88.

The wet processing module 90 includes an input/output chamber 91 for the transfer of substrates to and from the factory interface 82. The wet processing module 90 includes a robot 101 having one or more robot arms 92 to transfer substrates between the input/output chamber 91, one or more twin chamber 93, one or more bevel clean chambers 104, and one or more vapor dry chambers 106. Each twin chamber 93 includes a first substrate carrier 94 to hold a substrate during processing in chamber 95 and a second substrate carrier 97 to hold a substrate during processing in chamber 98. A transfer arm 100 transfers a substrate between chambers 95 and 98. Stations 95 and 98 may be a dielectric clean chamber, a copper clean chamber, an activation chamber, a post-activation clean chamber, a capping layer deposition chamber including an electroless deposition cell, a post-deposition clean chamber, a chamber adapted to perform one or more steps (e.g., a combined chamber that performs both a copper clean step and a post-activation clean step), and/or other wet processing chambers.

In one embodiment, an enclosure 102 is placed around the twin chamber 93 to fully enclose and isolate chambers 95 and 98 from the robot 101 and other processing chambers in the processing system 80. In one embodiment an inert gas source 103 and an exhaust system (not shown) are attached to the enclosure to provide a substantially inert environment (e.g., low partial pressure of oxygen, water, etc.) in and around the chambers 95 and 98 during processing. In one embodiment, a HEPA filter assembly (not shown) is placed over the chambers 95 and 98 and is placed in communication with the inert gas source 103 to deliver a relatively particle free and uniform flow of inert gas through the enclosure 102 and a around the chambers 95 and 98. The gas source 103 may be configured to provide an inert gas, such as nitrogen, helium, argon, mixtures thereof, or other gases commonly used in semiconductor processing, to the interior of processing enclosure 103 before, during, and after substrate processing steps. In one aspect of the invention, a door opening 107 is formed in a wall of the enclosure 102 to allow the robot 101 to transfer substrates to and from the chambers 95 and 98. In one aspect of the invention, a door (not shown) and a door actuator (not shown) are adapted to cover and seal-off the door opening 107 prior to starting a process(es) being performed in the chambers 95 and 98. In one aspect of the invention, when the door opening 102 is not covered by the door (not shown), the flow of the inert gas into the enclosure 102 is increased, to minimize the influx of contaminants into the enclosure 102.

FIG. 8B is a schematic top view of another embodiment of an integrated processing system 110 which may be utilized to perform methods 50-70. Of course, many other processing systems may also be used. The integrated processing system 110 includes a plurality of chambers or cells. In one aspect, it is preferable to perform certain steps in different chambers to reduce the likelihood of cross-contamination from the different chemical solutions being used. However, in performing certain steps in different chambers, queue time between the chambers may impact the particular selection and/or configuration of the various chambers.

Integrated processing system 110 includes a factory interface 112, vertically disposed processing chambers 120, one or more twin chambers 130, and an anneal module 118. The factory interface includes a plurality of bays, each accepting a substrate storage cassette 114, and at least one robot 116 to transfer substrates between the substrate storage cassettes 114, the vertically disposed processing chambers 120, and the anneal module 118.

The vertically disposed processing chambers 120 are adapted to process substrates in a vertical orientation. At least one vertically disposed processing chamber 120 is an input/output chamber for the transfer of substrates to and from the factory interface 112 and to and from robot 128 and at least one vertically disposed processing chamber 120 is a vapor drying chamber. The other vertically disposed processing chambers 120 can be one or more dielectric clean chambers, one or more copper clean chambers, one or more activation metal seed layer deposition chambers, one or more post-activation clean chambers, one or more post-deposition clean chambers, one or more bevel edge clean chambers, one or more rinse chambers, and/or other wet processing chambers. The vertically disposed processing chambers 120 may also perform other substrate processing functions.

The robot 128 transfer substrates between the vertically disposed processing chambers 120 and the one or more twin chambers 130. In one embodiment, the twin chamber 130 processes substrates in a substantially horizontal orientation. Each twin chambers 130 includes a first substrate carrier 134 to hold a substrate during processing in chamber 135 and a second substrate carrier 137 to hold a substrate during processing in chamber 138. A transfer arm 140 transfers a substrate between chambers 135 and 138. Chambers 135 and 138 may be a dielectric clean chamber, a copper clean chamber, an activation layer deposition chamber, a post-activation clean chamber, a capping layer deposition chamber including an electroless deposition cell, a post-deposition clean chamber, a bevel edge clean chamber, a chamber adapted to perform one or more cleaning steps (e.g., a combined chamber that performs both a copper clean step and a post-activation clean step), and/or other wet processing chambers. The integrated processing system 110 may further include a bath metrology unit 144 to supply solutions to the system 110 and may further include a controller 148.

In one embodiment, an enclosure 142 is placed around the twin chamber 130 to fully enclose and isolate chambers 135 and 138 from the robot 128 and other processing chambers in the integrated processing system 110. In one embodiment an inert gas source 103 and an exhaust system (not shown) are attached to the enclosure 142 to provide a substantially inert environment (e.g., low partial pressure of oxygen, water, etc.) in and around the chambers 135 and 135 during processing. In one embodiment, a HEPA filter assembly (not shown) is placed over the chambers 135 and 138 and is placed in communication with the inert gas source 103 to deliver a relatively particle free and uniform flow of inert gas through the enclosure 142 and a around the chambers 135 and 138. The gas source 103 may be configured to provide an inert gas, such as nitrogen, helium, argon, mixtures thereof, or other gases commonly used in semiconductor processing, to the interior of processing enclosure 142 before, during, and after substrate processing steps. In one aspect of the invention, a door opening 143 is formed in a wall of the enclosure 142 to allow the robot 128 to transfer substrates to and from the chambers 135 and 138. In one aspect of the invention a door (not shown) and a door actuator (not shown) are adapted to cover and seal-off the door opening 143 prior to starting a process(es) being performed in the chambers 135 and 138. In one aspect of the invention, when the door opening 143 is not covered by the door (not shown), the flow of the inert gas into the enclosure 142 is increased, to minimize the influx of contaminants into the enclosure 142.

FIG. 9 is a schematic cross-sectional view of one example of a substrate structure 71 including copper features 72 capped with capping layer 78. The substrate structure 71 includes a low-k dielectric layer 74 patterned and etched to form apertures 75, such as vias, trenchs, contact holes, or lines. Barrier layer 73, such as a tantalum-containing barrier layer or other suitable barrier layer, is formed over the apertures 75. Then, copper features 72 are formed over the barrier layer filling the aperture 75. A seed layer (not shown), such as a copper seed layer, a copper alloy seed layer or other suitable seed layer, may be formed between the barrier layer 73 and the copper features 72 to aid in deposition of the copper features 72 thereover. The capping layer 78 is formed, such as by the methods disclosed herein, selectively over the copper features 72. As shown, here a passivation layer is not used. In other embodiments, a capping layer may be used in conjunction with a passivation layer.

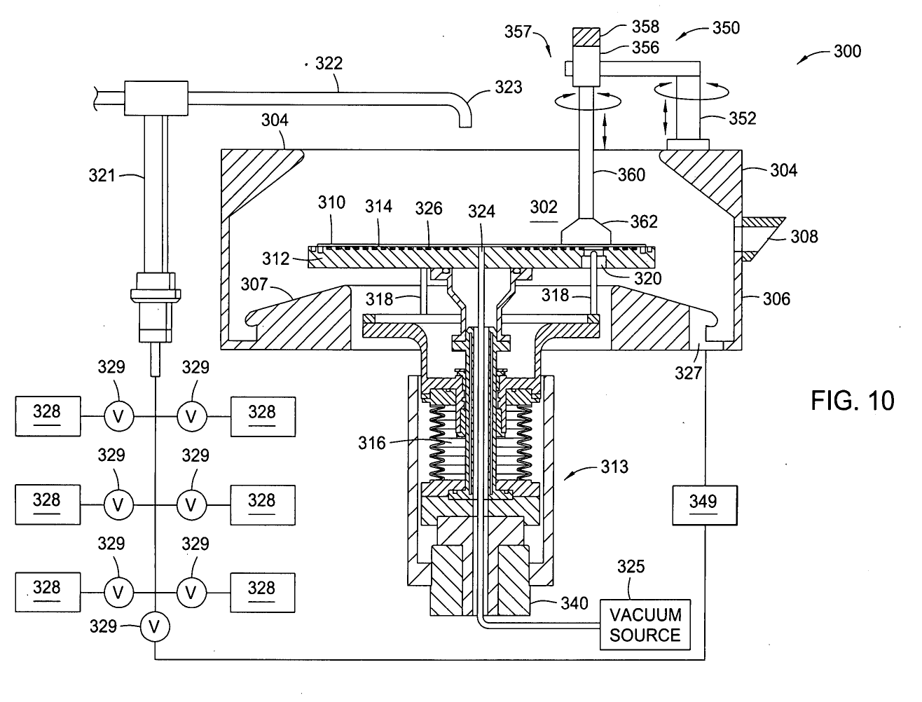

FIG. 10 illustrates a cross sectional view of a chamber 300 that can be adapted to perform all or part of the cleaning steps 52, 53, 55, 57 and 58 shown in method 50 and method 60. The chamber 300 includes a processing compartment 302 comprising a chamber top 304, side walls 306, and a bottom 307. A substrate support 312 is disposed in a generally central location in the chamber 300. The substrate support 312 includes a substrate receiving surface 314 to receive the substrate 310 in a “face-up” position. Having the substrate in a face-up position also lessens the complexity of the substrate transfer mechanisms, improves the ability to clean the substrate during processing, and allows the substrate to be transferred in a wet state to minimize contamination and/or oxidation of the substrate. In other embodiments the substrate may be oriented in a face-down or other substrate orientation without varying from the scope of the present invention.

The substrate support 312 may comprise a ceramic material (such as alumina Al₂O₃ or silicon carbide (SiC)), TEFLON™ coated metal (such as aluminum or stainless steel), a polymer material, or other suitable materials. TEFLON™ as used herein is a generic name for fluorinated polymers such as Tefzel (ETFE), Halar (ECTFE), PFA, PTFE, FEP, PVDF, etc. The substrate support 312 may further comprise embedded heated elements, especially for a substrate support comprising a ceramic material or a polymer material.

The chamber 300 further includes a slot 308 or opening formed through a wall thereof to provide access for a robot (not shown) to deliver and retrieve the substrate 310 to and from the chamber 300. Alternatively, the substrate support 312 may raise the substrate 310 through the chamber top 304 of the processing compartment to provide access to and from the chamber 300.

A lift assembly 316 may be disposed below the substrate support 312 and coupled to lift pins 318 to raise and lower lift pins 318 through apertures 320 in the substrate support 312. The lift pins 318 raise and lower the substrate 310 to and from the substrate receiving surface 314 of the substrate support 312.

A motor 340 may be coupled to the substrate support 312 to rotate the substrate support 312 to spin the substrate 310. In one embodiment, the lift pins 318 may be disposed in a lower position below the substrate support 312 to allow the substrate support 312 to rotate independently of the lift pins 318. In another embodiment, the lift pins 318, may rotate with the substrate support 312.

The substrate support 312 may be heated to heat the substrate 310 to a desired temperature. The substrate receiving surface 314 of the substrate support 312 may be sized to substantially receive the backside of the substrate 310 to provide uniform heating of the substrate 310.

A fluid input, such as a nozzle 323, may be disposed in the chamber 300 to deliver a fluid, such as a chemical cleaning solution, a chemical processing solution, and/or deionized water, to the surface of the substrate 310. The nozzle 323 may be disposed over the center of the substrate 310 to deliver a fluid to the center of the substrate 310 or may be disposed in any other position. The nozzle 323 may be disposed on a dispense arm 322 positioned over the chamber top 304 or through the sidewall 306 of the processing compartment 302. The dispense arm 322 may be moveable about a rotatable support member 321 which is adapted to pivot and swivel the dispense arm 322 and the nozzle 323 to and from the center of the substrate 310. Additionally or alternatively, a nozzle (not shown) may be disposed on the chamber top 304 or sidewalls 306 of the chamber 300 and adapted to spray a fluid in any desired pattern on the substrate 310.

A single or a plurality of fluid sources 328a-f (collectively referred to as “fluid sources”) may be coupled to the nozzle 323. Valves 329 may be coupled between the fluid sources 328 and the nozzle 323 to provide a plurality of different types of fluids. Fluid sources 328 may provide, for example and depending on the particular process, a chemical cleaning solution, a chemical processing solution, and/or deionized water. In one embodiment, the fluid path between the fluid sources 328 and the nozzle 323 may be heated in order to deliver a fluid to the substrate surface at a certain temperature. In one embodiment of the chamber 300, the fluid sources 328a-f are also adapted to deliver an electroless plating solution, such as, an activation solution, a post activation clean solution, a capping layer solution and/or a self-activating electroless deposition solution to perform an electroless deposition process on the surface of the substrate.

The chamber 300 further includes a drain 327 in order to collect and expel fluids used in the chamber 300. The bottom 307 of the processing compartment 302 may comprise a sloped surface to aid the flow of fluids used in the chamber 310 towards an annular channel in communication with the drain 327 and to protect the substrate support assembly 313 from contact with fluids. In one embodiment, the drain 327 may be configured to reclaim fluids used in the chamber.

In one embodiment, the substrate support 312 may be adapted to rotate. The rotational speed of the substrate support 312 may be varied according to a particular process being performed. In the case of deposition, the substrate support 312 may be adapted to rotate at relatively slow speeds, such as between about 1 revolution per minute (RPM) and about 500 RPMs, depending on the viscosity of the fluid, to spread the fluid across the surface of the substrate 310 by virtue of the fluid inertia. In the case of rinsing, the substrate support 312 may be adapted to spin at relatively medium speeds, such as between about 100 RPMs and about 500 RPMs. In the case of drying, the substrate support may be adapted to spin at relatively fast speeds, such as between about 500 RPMS and about 2000 RPMs to spin dry the substrate 310.

The substrate support 312 may include a vacuum port 324 coupled to a vacuum source 325 to supply a vacuum to the backside of the substrate to vacuum chuck the substrate 310 to the substrate support 312. Vacuum Grooves 326 may be formed on the substrate support 312 in communication with the vacuum port 324 to provide a more uniform vacuum pressure across the backside of the substrate 310 to hold the substrate 310 during rotation of the substrate support 312.

In one embodiment of the chamber 300, a brushing apparatus 350 is adapted to brush and clean the surface of a substrate mounted on the substrate support 312. The brushing apparatus 350 is configured to rotate and force a brush head 362 against the surface of the substrate 310 to remove the particle or other contaminants that may reside thereon. The substrate contacting surface of the brush head 362 may employ a polyvinyl acetate (PVA) material, a porous polystyrene material, a porous polyethylene material, or other porous or sponge-like material, and may also contain brushes made from nylon bristles or similar materials. The brushing apparatus 350 generally contains a mounting arm assembly 352, a rotation arm 354, and brush assembly 357. The brush assembly 357 generally contains an actuator 356, a shaft 360 and a brush head 362. The mounting arm assembly 352, which is adapted to rotate and position the brush assembly 357 over the surface of the substrate 310, can be mounted on the chamber top 304 of the chamber 300 or other suitable mounting surface. The mounting arm assembly 352 may contain one or more actuators or motors that can raise, lower and/or rotate the brush assembly 357 and rotation arm 354 into a desired position on the surface of the substrate 310. The rotation arm 354 is configured to connect the mounting arm assembly 352 to the brush assembly 357. The actuator 356, which mounted to the rotation arm 354 and the brush head 362 through the shaft 360, may be adapted to raise, lower and/or rotate the brush head 362 during processing. In one embodiment, the actuator 356 is used to force the brush head 362 against the surface of the substrate. In another embodiment, the mounting arm assembly 352 is adapted to force the brush head 362 against the surface of the substrate.

In one embodiment of the brushing apparatus 350, a sonic transducer 358 is attached to the brush assembly 352 so that ultrasonic or megasonic energy can be delivered to the substrate surface, through the brush head 362, to further enhance the cleaning process.

While the foregoing is directed to embodiments of the invention, other and further embodiments of the invention may be devised without departing from the basic scope thereof, and the scope thereof is determined by the claims that follow.

1. A method of processing a substrate having a substrate structure formed thereon, comprising the steps of:
vapor drying a substrate; and
forming a capping layer by an electroless deposition process over an exposed metal portion formed on a surface of the substrate.

2. The method of claim 1, wherein the substrate structure is vapor dried prior to forming the capping layer.

3. The method of claim 1, wherein the substrate structure is vapor dried after forming the capping layer.

4. The method of claim 1, wherein forming a capping layer by an electroless deposition process comprises:
forming an activation metal seed layer by an electroless deposition process over the exposed metal portion;
cleaning a surface of the substrate containing the exposed metal portion using a post-activation clean solution; and
forming a capping layer by an electroless deposition process over the exposed metal portion.

5. The method of claim 1, wherein forming a capping layer by an electroless deposition process comprises forming a capping layer by a self-activating electroless deposition process over the exposed metal portion.

6. The method of claim 1, further comprising applying a dielectric clean solution to the substrate.

7. The method of claim 6, wherein the substrate structure is vapor dried prior to applying the dielectric clean solution to the substrate structure.

8. The method of claim 6, wherein the substrate structure is vapor dried after applying the dielectric clean solution to the substrate structure.

9. The method of claim 1, further comprising cleaning a surface of the substrate containing the exposed metal portion by applying a metal clean solution to the substrate.

10. The method of claim 1, further comprising cleaning a surface of the substrate containing the exposed metal portion by applying a post-deposition clean solution to the substrate.

11. The method of claim 10, wherein the substrate is vapor dried after applying the post-deposition clean solution to the substrate.

12. The method of claim 1, further comprising cleaning a bevel edge of the substrate after forming the capping layer.

13. The method of claim 1, further comprising annealing the substrate after forming the capping layer.

14. The method of claim 10, further comprising annealing the substrate structure after applying the post-deposition clean solution to the substrate structure.

15. The method of claim 1, further comprising the steps of:
removing an unwanted metal layer on a surface of the substrate using a CMP process; and
cleaning the substrate surface to remove any contaminants leftover from the CMP process prior to forming the capping layer over the exposed metal portions.

16. A method of processing a substrate having a substrate structure formed thereon, comprising the steps of:
cleaning a surface of a substrate by performing a dielectric clean process;
cleaning a surface of a substrate by performing a metal clean process;
forming a capping layer by an electroless deposition process over an exposed metal portion formed on a surface of the substrate;
cleaning a surface of a substrate by performing a post-deposition clean process; and
vapor drying the substrate.

17. The method of claim 16, further comprising vapor drying the substrate prior to forming the capping layer.

18. The method of claim 16, further comprising vapor drying the substrate prior to cleaning the surface of the substrate by performing the dielectric clean process.

19. The method of claim 16, further comprising vapor drying the substrate after cleaning the surface of the substrate by performing the dielectric clean process.

20. The method of claim 16, wherein forming a capping layer by an electroless deposition process comprises:
forming an activation metal seed layer by an electroless deposition process over the exposed metal portion;
cleaning a surface of the substrate containing the exposed metal portion by performing a post-activation clean process; and
forming a capping layer by an electroless deposition process over the exposed metal portion.

21. The method of claim 16, wherein forming a capping layer by an electroless deposition process comprises forming a capping layer by a self-activating electroless deposition process over the exposed metal portion.

22. The method of claim 16, further comprising cleaning a bevel edge of the substrate after forming the capping layer.

23. The method of claim 16, further comprising annealing the substrate after forming the capping layer.

24. The method of claim 16, further comprising annealing the substrate structure after applying the post-deposition clean solution to the substrate.

25. A fluid processing platform adapted to process a substrate having a substrate structure formed thereon, comprising:
a first processing chamber, wherein the first processing chamber is an electroless deposition chamber; and
a second processing chamber, wherein the second processing chamber is a vapor drying chamber.

26. The fluid processing platform of claim 25, wherein the first processing chamber is also adapted to perform one or more cleaning processes selected from a group consisting of a dielectric clean process, a copper clean process, a post-deposition clean process, and a bevel edge clean process.

27. The fluid processing platform of claim 25, wherein the first processing chamber contains a brushing apparatus to clean a surface of a substrate.

28. The fluid processing platform of claim 25, wherein the first processing chamber contains a sonic transducer.

29. The fluid processing platform of claim 25, wherein a substrate processed in the second processing chamber is processed in a substantially vertical orientation.

30. A fluid processing platform adapted to process a substrate having a substrate structure formed thereon, comprising:
a first processing chamber, wherein the first processing chamber is adapted to deposit an activation metal seed layer by use of an electroless process;
a second processing chamber, wherein the second processing chamber is adapted to deposit a capping layer by use of an electroless process; and
a vapor drying chamber that is adapted to process a substrate in a substantially vertical orientation.

31. The fluid processing platform of claim 30, further comprising a wet processing chamber that is adapted to perform a process selected from a group consisting of a dielectric clean chamber, a copper clean chamber, a post-activation clean chamber, or a combined chamber adapted to perform a combination thereof.

32. The fluid processing platform of claim 30, further comprising one or more bevel edge clean chambers.

33 The fluid processing platform of claim 30, further comprising one or more anneal chambers.

34. A fluid processing platform adapted to process a substrate having a substrate structure formed thereon, comprising:
an electroless processing chamber that is adapted to process a substrate in a substantially horizontal orientation;
a vapor drying chamber that is adapted to process a substrate in a substantially vertical orientation; and
a wet processing chamber that is adapted to perform a process selected from a group consisting of a dielectric clean chamber, a copper clean chamber, an electroless activation layer deposition chamber, a post-activation clean chamber, or a combined chamber adapted to perform a combination thereof.

35. The fluid processing platform of claim 34, further comprising:
an enclosure having a plurality of walls that forms a processing region that contains the electroless processing chamber and the wet processing chamber;
a robot mounted inside the processing region that is adapted to transfer a substrate between the electroless processing chamber and the wet processing chamber;
an inert gas source adapted to inject an inert gas into the processing region; and
an exhaust source adapted to remove gases from the processing region.

36 The fluid processing platform of claim 34, further comprising one or more bevel edge clean chambers.

37 The fluid processing platform of claim 34, further comprising one or more anneal chambers.

38. The fluid processing platform of claim 34, wherein the wet processing chamber contains a brushing apparatus to clean a surface of a substrate.

39. The fluid processing platform of claim 34, wherein the wet processing chamber contains a sonic transducer.
